(19) United States
(12) Patent Application Publication
(10) Pub. No.: US 2025/0118626 A1
(43) Pub. Date: Apr. 10, 2025

(54) POWER SEMICONDUCTOR MODULE COMPRISING A POTTING BODY AND PRODUCTION METHOD

(71) Applicant: SEMIKRON DANFOSS ELEKTRONIK GMBH & CO. KG, NUREMBERG (DE)

(72) Inventors: Markus DÜSEL, Hallerndorf (DE); Stefan HUXHOLD, Karlsruhe (DE); Stefan OEHLING, Uttenreuth (DE); Michael UNÜTZER, Oberasbach, DE (US)

(73) Assignee: SEMIKRON DANFOSS ELEKTRONIK GMBH & CO. KG, NUREMBERG (DE)

(21) Appl. No.: 18/903,889

(22) Filed: Oct. 1, 2024

(30) Foreign Application Priority Data
Oct. 5, 2023 (DE) 10 2023 127 129.6

(51) Int. Cl. H01L 23/40; H01L 21/56; H01L 23/00; H01L 23/29; H01L 23/31; H01L 23/498

(52) U.S. Cl. CPC H01L 23/4006; H01L 23/293; H01L 23/3107; H01L 23/498; H01L 24/37; H01L 24/40; H01L 21/56; H01L 2023/4081; H01L 2224/37033; H01L 2224/40227

(57) ABSTRACT

A power semiconductor module having a substrate, with a power semiconductor component, a connecting device, external terminal elements, a potting body and a pressure device, wherein the substrate has an insulant body and substrate conductor tracks, and the power semiconductor component is on a substrate conductor track, the connecting device is embodied as a film stack having a first electrically conductive film, a second electrically conductive film and an electrically insulating film arranged therebetween, wherein the external terminal elements each have a contact device for a substrate conductor track. The potting body completely covers the entire connecting device, envelops the substrate, and the external terminal elements apart from contact portions, and the pressure device exerts pressure on the potting body directly with a spring.

### CROSS REFERENCES TO RELATED APPLICATIONS

This application relates to and claims priority to DE 10 2023 127 129.6 filed Oct. 5, 2023, the entire contents of which are incorporated herein fully by reference.

### FIGURE SELECTED FOR PUBLICATION

FIG. 2

### BACKGROUND OF THE INVENTION

### Field of the Invention

The invention describes a production method and a power semiconductor module comprising a substrate, comprising a power semiconductor component arranged thereon, comprising a connecting device, comprising external terminal elements, comprising a potting body and comprising a pressure device.

### Description of the Related Art

DE 10 2013 104 949 B3 discloses a switching device comprising a substrate, a power semiconductor component, a connecting device, load terminal devices and a pressure device. In this case, the substrate has electrically insulated conductor tracks, and a power semiconductor component is arranged on a conductor track. The connecting device is embodied as a film composite comprising an electrically conductive film and an electrically insulating film and has a first and a second main surface. The switching device is thereby connected internally in a circuit-conforming manner. The pressure device has a pressure body having a first cutout, projecting from which a pressure element is arranged, wherein the pressure element presses onto a portion of the second main surface of the film composite and in this case said portion is arranged within the surface of the power semiconductor component in projection along the normal direction with respect to the power semiconductor component.

DE 10 2017 125 052 A1 relates to a power semiconductor module comprising a switching device, which has a substrate, a power semiconductor component and a film stack, and comprising a pressure device embodied to be movable in the normal direction with respect to the substrate, wherein the film stack has a first main surface facing the substrate and a second main surface facing away from the substrate, wherein the pressure device has a pressure body and a first metal spring, wherein the pressure body exerts a force on the first metal spring in the direction of the substrate, wherein the first metal spring exerts pressure on a first region of the second main surface in the direction of the power semiconductor component by means of a pressure transmission surface of the first metal spring, which pressure transmission surface faces the first region of the second main surface, and here the first region of the second main surface and the pressure transmission surface of the first metal spring are arranged, in the normal direction with respect to the substrate, above a first surface of the power semiconductor component, which first surface faces away from the substrate, and in a manner aligned with the first surface of the power semiconductor component.

### ASPECTS AND OBJECTS OF THE INVENTION

With knowledge of the aforementioned circumstances, the invention is based on the object of simplifying and structurally reinforcing the construction of the known power semiconductor module and presenting a method for producing such a power semiconductor module.

This object is achieved according to the invention by a power semiconductor module comprising a substrate, comprising a power semiconductor component arranged thereon, comprising a connecting device, comprising external terminal elements, comprising a potting body and comprising a pressure device, wherein the substrate has an insulant body and substrate conductor tracks arranged thereon, wherein the power semiconductor component is arranged on one of these substrate conductor tracks and is electrically conductively connected thereto, wherein the connecting device is embodied as a film stack comprising a first electrically conductive film, comprising a second electrically conductive film and an electrically insulating film arranged therebetween, wherein the external terminal elements each have a contact device to an assigned substrate conductor track, wherein the potting body completely covers the entire connecting device and envelops the substrate and also the external terminal elements apart from external contact portions, and wherein the pressure device is embodied to exert pressure on the potting body directly by means of a spring element or on the potting body indirectly exclusively by way of a metal plate.

An aspect of the present invention further provides a power semiconductor module comprising a substrate, comprising a power semiconductor component arranged thereon, comprising a connecting device, comprising external terminal elements, comprising a potting body and comprising a pressure device, wherein the substrate has an insulant body and substrate conductor tracks arranged thereon, wherein the power semiconductor component is arranged on one of these substrate conductor tracks, wherein the connecting device is embodied as a film stack comprising a first electrically conductive film, comprising a second electrically conductive film and an electrically insulating film arranged therebetween, wherein the external terminal elements each have a contact device to an assigned substrate conductor track, wherein the potting body completely covers the entire connecting device and envelops the substrate and also the external terminal elements apart from external contact portions, and wherein the pressure device is embodied to exert pressure on the potting body directly by means of a spring element.

When the power semiconductor module is used, the pressure of the pressure device is thus exerted on the potting body pressing directly on the connecting device pressing directly on the power semiconductor components, and the substrate is thus pressed onto a cooling device. Consequently, the construction is simple and has additional stability by virtue of the potting body.

It is advantageous if the electrically conductive films each embody a plurality of film conductor tracks.

It may be advantageous if the potting body is embodied as an epoxy resin.

It is preferred if the potting body has a modulus of elasticity of between 2000 MPa and 6000 MPa, preferably between 3000 MPa and 4200 MPa. Alternatively or additionally, it may be preferred if the potting body has a coefficient of linear expansion CTE of between 1 ppm/K and 200 ppm/K, preferably between 2 ppm/K and 50 ppm/K and more particularly preferably between 3 ppm/K and 20 ppm/K.

It may be advantageous if the potting body has an intermediate potting body, which directly covers the connecting device and which preferably has a modulus of elasticity that is lower by at least 10%, advantageously by at least 20%.

It may be preferred if the substrate, the connecting device and the potting bodies and, if present, also the metal plate have in each case mutually aligned and in each case continuous cutouts through which a pressure introducing element projects.

It may also be preferred if a surface of the potting body facing away from the substrate has a contour element, by way of example projecting like a pimple.

In the case of a power semiconductor module having a metal plate, it may be preferred if a surface of the metal plate facing away from the substrate has a contour element, by way of example projecting like a pimple.

It may be particularly advantageous if the spring element has a finger with a finger contact area. In this case, it may additionally be advantageous if the finger contact area is aligned with a power semiconductor component or with the midpoint of a group of two or three power semiconductor components in the normal direction.

The abovementioned object is furthermore achieved according to the invention by a method for producing such a power semiconductor module comprising the following work steps in particular in the order a-b-c-d or a-b-d-c:
a. embodying a substrate with a power semiconductor component arranged on one of the substrate conductor tracks and connected thereto;
b. arranging the connecting device;
c. arranging the external terminal elements and connecting contact devices of these external terminal elements to assigned substrate conductor tracks;
d. covering and enveloping the entire connecting device, the substrate and the external terminal elements, with the exception of external contact portions, with a potting compound which, when cured, embodies the potting body.

It is preferred if after the last method step, the spring device is arranged.

Of course, unless this is explicitly excluded or excluded per se or contradicts the concept of the invention, the features or groups of features mentioned in the singular in each case, by way of example the power semiconductor component, can be present multiple times in the power semiconductor module according to the invention.

It goes without saying that the various configurations of the invention, irrespective of whether they are mentioned in connection with the power semiconductor module or with the method, can be realized individually or in any combinations in order to achieve improvements. In particular, the features mentioned and explained above and hereinafter are able to be used not only in the combinations indicated, but also in other combinations or by themselves, without departing from the scope of the present invention.

Further explanations of the invention, advantageous details and features will become apparent from the following description of the exemplary embodiments of the invention schematically illustrated in the figures or respective parts thereof.

The above and other aspects, features and advantages of the present invention will become apparent from the following description read in conjunction with the accompanying drawings, in which like reference numerals designate the same elements.

### BRIEF DESCRIPTION OF THE DRAWINGS

FIG. 1 shows one step of the method according to the invention for producing a power semiconductor module according to the invention.

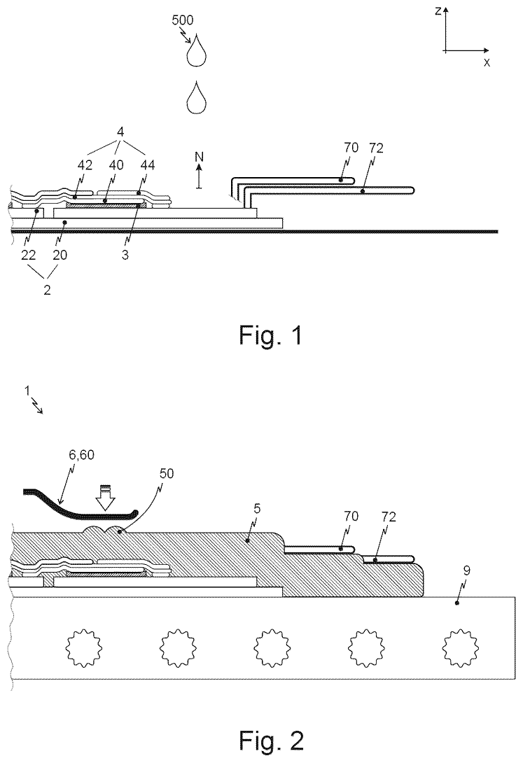

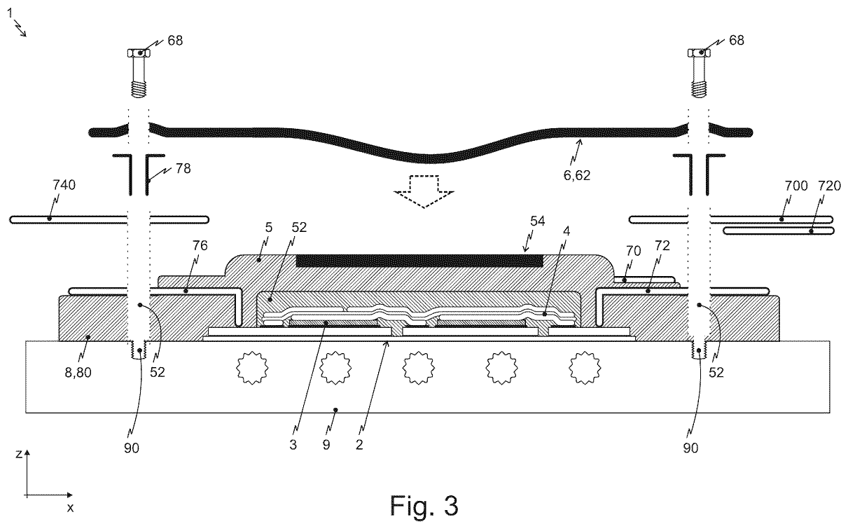

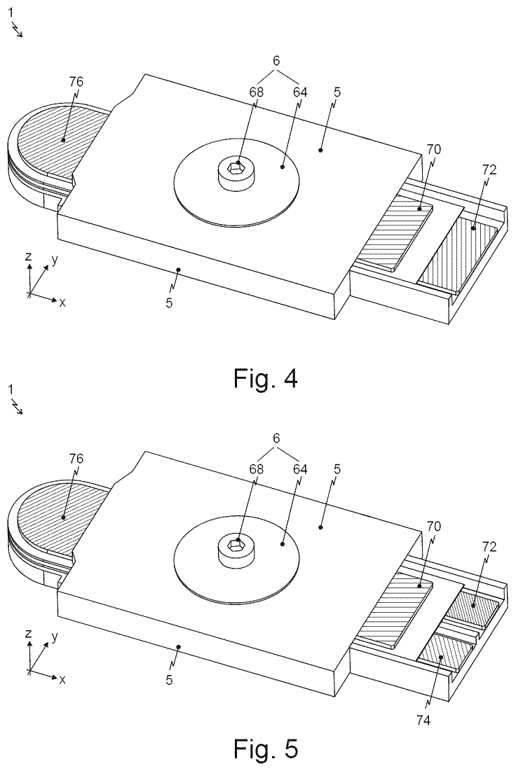

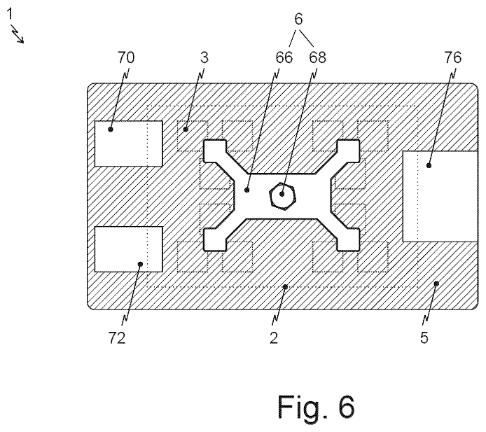

FIG. 2 shows a section through a first configuration of a power semiconductor module according to the invention.

FIG. 3 shows a second configuration of a power semiconductor module according to the invention.

FIGS. 4 and 5 show three-dimensional views of power semiconductor modules according to the invention.

FIG. 6 shows a plan view of a power semiconductor module according to the invention.

### DETAILED DESCRIPTION OF THE PREFERRED EMBODIMENTS

Reference will now be made in detail to embodiments of the invention. Wherever possible, same or similar reference numerals are used in the drawings and the description to refer to the same or like parts or steps. The drawings are in simplified form and are not to precise scale. The word ‘couple’ and similar terms do not necessarily denote direct and immediate connections, but also include connections through intermediate elements or devices. For purposes of convenience and clarity only, directional (up/down, etc.) or motional (forward/back, etc.) terms may be used with respect to the drawings. These and similar directional terms should not be construed to limit the scope in any manner. It will also be understood that other embodiments may be utilized without departing from the scope of the present invention, and that the detailed description is not to be taken in a limiting sense, and that elements may be differently positioned, or otherwise noted as in the appended claims without requirements of the written description being required thereto.

Various operations may be described as multiple discrete operations in turn, in a manner that may be helpful in understanding embodiments of the present invention; however, the order of description should not be construed to imply that these operations are order dependent.

FIG. 1 shows one method step, more precisely method step d), of the method according to the invention for producing a power semiconductor module according to the invention. The starting point is a substrate 2 defining a normal direction N. This substrate 2 is embodied here purely by way of example as a ceramic substrate 20 that is routine in the art, with a plurality of substrate conductor tracks 22 composed of copper. A power semiconductor component 3, here purely by way of example a silicon carbide MOS-FET, is arranged on one of these substrate conductor tracks 22 in a materially bonded and electrically conductive manner.

This power semiconductor component 3 is connected to a further substrate conductor track 22 in a circuit-conforming manner by means of a module-internal connecting device 4. The connecting device 4 is embodied as a film stack composed of two electrically conductive films 40, 44 with an electrically insulating film 42 arranged between the conductive films. The electrically conductive films 40, 44 are structured and thus form in each case mutually insulated film conductor tracks.

The illustration furthermore shows external terminal elements 70, 72, of which two DC voltage terminal elements are shown here, which embody a stack in portions in order to minimize parasitic inductances. These DC voltage terminal elements 70, 72 have respective contact areas that are contactable from the normal direction N; also cf. FIGS. 4 and 5.

Before this method step illustrated here, the external terminal elements 70, 72, more precisely their contact elements, were connected to assigned substrate conductor tracks 22. The illustration now shows the beginning of the covering of the power semiconductor component 3, the connecting device 4 and parts of the external terminal elements, cf. FIG. 2, with a potting compound 500.

FIG. 2 shows a section through a first configuration of a power semiconductor module 1 according to the invention arranged on a cooling device 9, here a liquid cooling device. The original potting compound 500, in the cured state, now embodies a potting body 5 composed of an epoxy resin, having a modulus of elasticity of 3500 MPa and a CTE value of 5 ppm/K.

The illustration furthermore shows a pressure device 6 comprising a spring element 60, which directly, i.e. immediately, exerts pressure on the potting body 5, here more precisely on two pimple-like contour elements 50 projecting in the normal direction N and embodied integrally with the rest of the potting body, and thus establishes a thermally conductive connection between the power semiconductor component 3 and the cooling device 9. As a simplification, a metallic baseplate can also be provided here instead of an explicit cooling device 9.

FIG. 3 shows a second configuration of a power semiconductor module 1 according to the invention, wherein here the potting body 5 additionally has a metal plate 54, facing the spring element 62 of the pressure device 6. This metal plate 54 serves for better pressure distribution over the potting body 5, which otherwise has the same specifications mentioned above.

The potting body 5 and also the pressure device have two cutouts aligned in each case in the normal direction N, through which cutouts there extends in each case a screw as pressure introducing body 68. This screw 68 further extends through two connecting elements 700, 740 and through two of the external terminal elements 72, 76, more precisely the external load terminal elements, and finds an abutment 90 in the cooling device 9. In this case, a further moulded insulant body 78 is arranged for electrically insulating the screw 68. The connecting elements 700, 720, 760 are connected to an electric motor or to a battery, by way of example.

FIGS. 4 and 5 show three-dimensional views of power semiconductor modules 1 according to the invention, with a fundamental construction in accordance with FIG. 4. Both configurations have a central cutout, through which a screw as pressure introducing element 68 extends right into a cooling device. The spring element 66 of the pressure device 6 itself is embodied here as a disc spring.

In contrast to the potting bodies 5 of the first configuration, the potting body 5 of this configuration has an intermediate potting body 52, which directly covers the connecting device 4 and thus also the power semiconductor component and which has a modulus of elasticity 20% lower than that of the rest of the potting body 5 and, moreover, is likewise embodied as an epoxy resin.

FIG. 4 shows a power semiconductor module 1 comprising two external DC voltage terminal elements 70, 72, and one external AC voltage terminal element 76. The circuit embodied in this power semiconductor module 1 is a two-level half-bridge circuit.

FIG. 5 shows a power semiconductor module 1 comprising three external DC voltage terminal elements 70, 72, 74 and one external AC voltage terminal element 76. The circuit embodied in this power semiconductor module 1 is a three-level half-bridge circuit.

The respective contactable contact areas of the external terminal elements 70, 72, 74, 76 are illustrated in a hatched manner.

FIG. 6 shows a plan view of a power semiconductor module 1 according to the invention. In this case, the two external DC voltage terminal elements 70, 72 are configured next to one another as viewed from the normal direction N, i.e. not in a manner forming a stack.

The spring element 66 of the pressure device 6 is of spider-like design with a plurality of, here four, fingers, the finger contact areas of which, for introducing pressure onto the potting body 5, are each assigned to a group of power semiconductor components 3 and are aligned with the midpoint thereof as viewed from the normal direction N.

The above disclosure is sufficient to enable one of ordinary skill in the art to practice the invention, and provides a mode of practicing the invention. While this is a full and complete disclosure of the preferred embodiments of this invention, it is does not limit the invention to the exact construction, dimensional relationships, and operations shown and described. Various modifications, alternative constructions, changes and equivalents will readily occur to those skilled in the art and may be employed, as suitable, without departing from the true spirit and scope of the invention. Such changes might involve alternative materials, components, structural arrangements, sizes, shapes, forms, functions, operational features or the like.

Also, the inventors intend that only those claims which use the specific and exact phrase “means for” are intended to be interpreted under 35 USC 112. The structure, device, and arrangement herein is noted and well supported in the entire disclosure. Moreover, no limitations from the specification are intended to be read into any claims, unless those limitations are expressly included in the claims.

Having described at least one of the preferred embodiments of the present invention with reference to the accompanying drawings, it will be apparent to those skills that the invention is not limited to those precise embodiments, and that various modifications and variations can be made in the presently disclosed system without departing from the scope or spirit of the invention. Thus, it is intended that the present disclosure covers modifications and variations of this disclosure provided they come within the scope of the appended claims and their equivalents.

Although only a few embodiments have been disclosed in detail above, other embodiments are possible and the inventors intend these to be encompassed within this specification. The specification describes certain technological solutions to solve the technical problems that are described expressly and inherently in this application. This disclosure describes embodiments, and the claims are intended to cover any modification or alternative or generalization of these embodiments which might be predictable to a person having ordinary skill in the art.

Therefore, the above description and illustrations should not be construed as limiting the scope of the invention, which is defined by the claims set out herein.

What is claimed is:

1. A power semiconductor module (1), comprising:
a substrate (2) with a power semiconductor component (3) arranged thereon;
a connecting device (4), having a plurality of external terminal elements (70, 72, 74, 76);
each said external terminal element comprising a potting body (5) and a pressure device (6);
wherein the substrate (2) has an insulant body (20) and substrate conductor tracks (22) arranged thereon;
wherein the power semiconductor component (3) is arranged on one of the substrate conductor tracks (22) and is electrically conductively connected thereto;
wherein the connecting device (4) is embodied as a film stack having a first electrically conductive film (40), a second electrically conductive film (44) and an electrically insulating film (42) arranged therebetween;
wherein the external terminal elements (70, 72, 74, 76) each have a contact device to an assigned substrate conductor track (22);
wherein the potting body (5) completely covers the entire connecting device (4) and envelops the substrate (2) and also the external terminal elements (70, 72, 74, 76) apart from external contact portions; and
wherein the pressure device (6) is embodied to exert pressure on the potting body (5) by one of a direct contact by a spring element (60, 62, 64, 66) on the potting body (5) and an indirect contact by the spring element (60, 62, 64, 66) on a metal plate (54) that is on the potting body (5).

2. The power semiconductor module, according to claim 1, wherein:
the electrically conductive films (40, 44) each embody film conductor tracks.

3. The power semiconductor module, according to claim 1, wherein:
the potting body (5) is embodied as an epoxy resin.

4. The power semiconductor module, according to claim 1, wherein:
the potting body (5) has a modulus of elasticity of between 2000 MPa and 6000 MPa.

5. The power semiconductor module, according to claim 1, wherein:
the potting body (5) has a coefficient of linear expansion CTE of between 1 ppm/K and 200 ppm/K.

6. The power semiconductor module, according to claim 1, wherein:
the potting body (5) has an intermediate potting body (52), which directly covers the connecting device (4) and that has a modulus of elasticity that is lower by at least 10%.

7. The power semiconductor module, according to claim 1, wherein:
the substrate (2) and the connecting device (4) and, if present, also the metal plate (54) have in each case mutually aligned and in each case continuous cutouts through which a pressure introducing element (68) projects.

8. The power semiconductor module, according to claim 1, wherein:
a surface of the potting body (5) facing away from the substrate (2) has a contour element (50).

9. The power semiconductor module, according to claim 1, wherein:
said spring device (6) is on the potting body (5) and exerts pressure indirectly exclusively by said metal plate (54); and
wherein a surface of the metal plate (54) facing the substrate (2) has at a contour element (50).

10. The power semiconductor module, according to claim 8, wherein:
the contour element (50) is arranged in a manner aligned with a power semiconductor component (3) in a normal direction (N) with respect to the substrate (2).

11. The power semiconductor module, according to claim 8, wherein:
the contour element (50) is embodied in a manner projecting like a rounded protuberance.

12. The power semiconductor module, according to claim 1, wherein:
the spring element (66) has a finger with a finger contact area.

13. The power semiconductor module, according to claim 12, wherein:
the finger contact area is aligned with the power semiconductor component (3) or with a midpoint of a group of at least two of the power semiconductor components (3) in the normal direction (N).

14. A method for producing a power semiconductor module (1), comprising the steps of:
providing a power semiconductor module (1), according to claim 1, assembled according to the following work steps in the order of one of (i) a-b-c-d or (ii) a-b-d-c:
a. embodying a substrate (2) with a power semiconductor component (3) arranged on one of the substrate conductor tracks (22) and connected thereto;
b. arranging the connecting device (4);
c. arranging the external terminal elements (70, 72, 74, 76) and connecting contact devices of these external terminal elements (70, 72, 74, 76) to assigned substrate conductor tracks (22);
d. covering and enveloping the entire connecting device (4), the substrate (2) and the external terminal elements (70, 72, 74, 76), with the exception of external contact portions, with a potting compound (500) which, when cured, embodies the potting body (5).

15. The method, according to claim 14, wherein:
after the last method step, the spring device (6) is arranged.
